(19) United States
(12) Patent Application Publication
(10) Pub. No.: US 2011/0126875 A1
(43) Pub. Date: Jun. 2, 2011

(54) CONDUCTIVE CONTACT LAYER FORMED ON A TRANSPARENT CONDUCTIVE LAYER BY A REACTIVE SPUTTER DEPOSITION

(76) Inventors: Hien-Minh Huu Le, (US); Valery V. Komin, (US); David Tanner, (US); Mohd Fadzli Anwar Hassan, (US); Tzay-Fa Su, (US); Dapeng Wang, (US)

(21) Appl. No.: 12/628,569

(22) Filed: Dec. 1, 2009

(51) Int. Cl. H01L 31/042; C23C 14/34; H01L 31/06

(52) U.S. Cl. 136/244; 204/192.17; 136/256

(57) ABSTRACT

Methods for sputter depositing a transparent conductive layer and a conductive contact layer are provided in the present invention. In one embodiment, the method includes forming a transparent conductive layer on a substrate by materials sputtered from a first target disposed in a reactive sputter chamber, and forming a conductive contact layer on the transparent conductive layer by materials sputtered from a second target disposed in the reactive sputter chamber.

### BACKGROUND OF THE DISCLOSURE

1. Field of the Invention

The present invention relates to methods and apparatus for forming a conductive contact layer on a transparent conductive layer, more specifically, for reactively sputter depositing a conductive contact layer on a transparent conductive layer for photovoltaic devices.

2. Description of the Background Art

Photovoltaic (PV) devices or solar cells are devices which convert sunlight into direct current (DC) electrical power. PV or solar cells typically have one or more p-n junctions. Each junction comprises two different regions within a semiconductor material where one side is denoted as the p-type region and the other as the n-type region. When the p-n junction of the PV cell is exposed to sunlight (consisting of energy from photons), the sunlight is directly converted to electricity through the PV effect. PV solar cells generate a specific amount of electric power and cells are tiled into modules sized to deliver a desired amount of system power. PV modules are created by connecting a number of PV solar cells and are then joined into panels with specific frames and connectors.

Several types of silicon films, including microcrystalline silicon film (μc-Si), amorphous silicon film (a-Si), polycrystalline silicon film (poly-Si) and the like, may be utilized to form PV devices. A transparent conductive layer or a transparent conductive oxide (TCO) layer is often used as a top surface electrode, often referred as back reflector, disposed on the top of the PV solar cells. Alternatively, the transparent conductive layer is also used between the substrate and a photoelectric conversion unit. The transparent conductive film must have high optical transmittance in the visible or higher wavelength region to facilitate transmitting sunlight into the solar cells without adversely absorbing or reflecting light energy. Certain degree of texture or surface roughness of the transparent conductive layer is also desired to assist sunlight trapping in the layers by promoting light scattering. However, insufficient transparency of the transparent conductive layer may adversely reflect light back to the environment, resulting in a diminished amount of sunlight entering the PV cells and a reduction in the photoelectric conversion efficiency. Furthermore, at the interface of the transparent conductive layer and adjacent layers utilized to form junction cells, different optical properties between each film layer will result in mismatch of the film refractive index, causing light loss when transmitting light through film layers. Additionally, mismatched film refractive index and film properties may also result in high contact resistance at the interface of the transparent conductive layer and adjacent layers, thereby reducing carrier mobility in the film layers formed within the PV cells.

Therefore, there is a need for an improved method for forming an good interface between a transparent conductive film and junction cells with low contact resistance, low light transmission loss and smooth transition of film refractive index that provides high conversion efficiency of PV cells.

### SUMMARY OF THE INVENTION

Methods for sputter deposition of a conductive contact layer between a transparent conductive layer and a junction cell with low contact resistance and low light transmission loss suitable for use in PV cells are provided in the present invention. In one embodiment, a method of sputter depositing a conductive contact layer comprises forming a transparent conductive layer on a substrate by materials sputtered from a first target disposed in a reactive sputter chamber, and forming a conductive contact layer on the transparent conductive layer by materials sputtered from a second target disposed in the reactive sputter chamber.

In another embodiment, a method of forming a transparent conductive layer includes providing a substrate in a reactive sputter processing chamber, forming a transparent conductive layer on the substrate in the reactive sputter processing chamber, and forming a conductive contact layer on the transparent conductive layer in the reactive sputter processing chamber, wherein the conductive contact layer comprises dopants doped into a base material, wherein the dopants are selected from a group consisting of aluminum containing materials, niobium containing materials, tungsten containing materials, alloys thereof and combinations thereof, and the base material is a titanium containing material.

In yet another embodiment, a film stack for a PV solar cell includes a substrate having a transparent conductive layer disposed thereon, and a conductive contact layer deposited on the transparent conductive layer, wherein the conductive contact layer comprises dopants doped into a base material, wherein the dopants is selected from a group consisting of aluminum containing materials, niobium containing materials, tungsten containing materials, alloys thereof and combinations thereof, and the base material is a titanium containing material, wherein the transparent conductive layer and the conductive contact layer are formed within a single reactive sputter processing chamber.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a schematic cross-sectional view of one embodiment of a process chamber in accordance with the invention;

FIG. 2 depicts a process flow diagram for depositing a conductive contact layer on a transparent conductive layer in accordance with one embodiment of the present invention;

FIGS. 3A-3F depict cross sectional views of a silicon-based thin film PV solar cell at different manufacture stages in accordance with one embodiment of the present invention;

FIGS. 4A-4B depict exemplary cross sectional views of a tandem type PV solar cell in accordance with one embodiment of the present invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides methods for sputter depositing a conductive contact layer on a transparent conductive layer with low contact resistance, low light absorption, high film transparency and high film conductivity suitable for use in the fabrication of solar cells. The conductive contact layer reduces the likelihood of light loss when transmitting light from the substrate through the transparent conductive layer to the adjacent junction cells. In one embodiment, different dopant materials may be doped into the conductive contact layer to improve the optical and electrical properties in the conductive contact layer.

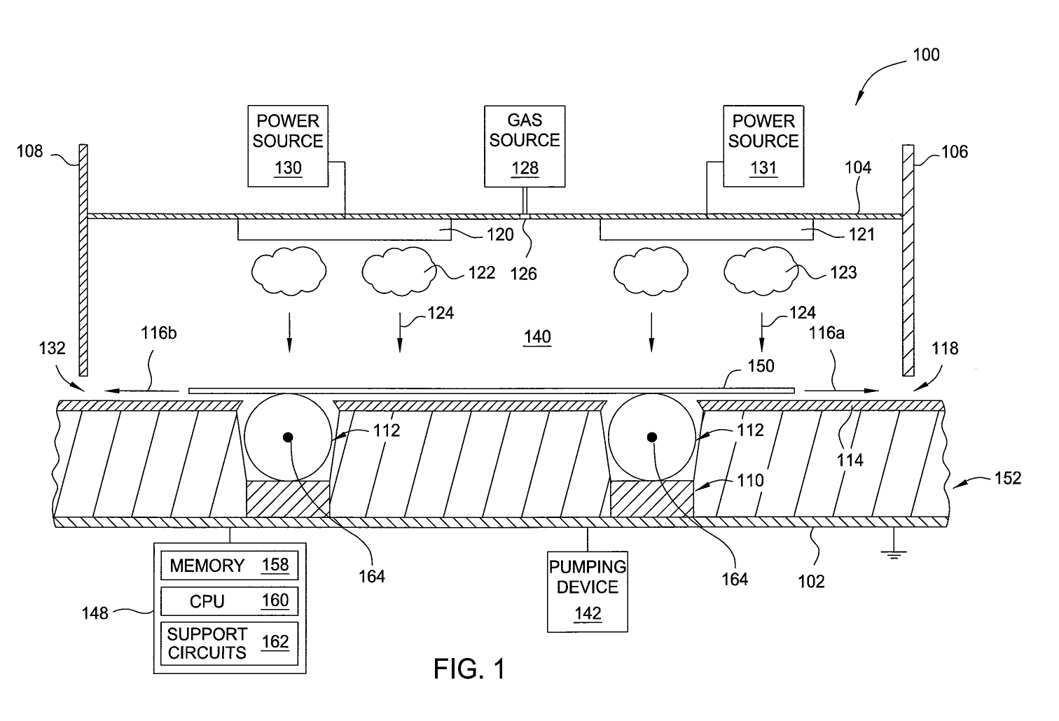

FIG. 1 illustrates an exemplary reactive sputter process chamber 100 suitable for sputter depositing materials according to one embodiment of the invention. One example of the process chamber that may be adapted to benefit from the invention is a PVD process chamber, available from Applied Materials, Inc., located in Santa Clara, Calif. It is contemplated that other sputter process chambers, including those from other manufactures, may be adapted to practice the present invention.

The processing chamber 100 includes a top wall 104, a bottom wall 102, a front wall 106 and a back wall 108, enclosing an interior processing region 140 within the process chamber 100. At least one of the walls 102, 104, 106, 108 is electrically grounded. The front wall 106 includes a front substrate transfer port 118 and the back wall 108 includes a back substrate transfer port 132 that facilitate substrate entry and exit from the processing chamber 100. The front transfer port 118 and the back transfer port 132 may be slit valves or be sealable by suitable doors that can maintain vacuum within the processing chamber 100. The transfer ports 118, 132 may be coupled to a transfer chamber, load lock chamber and/or other chambers of a substrate processing system.

One or more PVD targets, such as a first target 120 and a second target 121, may be mounted to the top wall 104 to provide a material source that can be sputtered from the targets 120, 121 and deposited onto the surface of the substrate 150 during a PVD process. The targets 120, 121 may be fabricated from materials utilized for deposition species. High voltage power supplies, such as power sources 130, 131, are connected to the targets 120, 121 respectively to facilitate sputtering materials from the targets 120, 121. In one embodiment, the targets 120, 121 may be fabricated from the same materials that may sputter deposit the same materials on the substrate 150 to form multiple layers on the substrate 150. In another embodiment, the targets 120, 121 may be configured to have different materials so that different material layers may be consecutively formed on the substrate 150 to meet different process requirements or junction cell configurations. In one embodiment, the first target 120 may be fabricated from a material containing zinc (Zn) while the second target 121 may be fabricated from a material containing titanium (Ti), tantalum (Ta) or aluminum (Al). In one embodiment, the first target 120 may be fabricated from materials including metallic zinc (Zn), zinc alloy, zinc oxide and the like and the second target 121 may be fabricated from materials including metallic titanium (Ti), titanium (Ti) alloy, titanium oxide (TiO₂), tantalum (Ta), tantalum (Ta) alloy, tantalum oxide (Ta₂O₅), aluminum (Al), aluminum (Al) alloy, aluminum oxide (Al₂O₃), and the like.

Furthermore, different dopant materials, such as aluminum containing materials, boron containing materials, tungsten containing materials, titanium containing materials, tantalum containing materials and the like, may be doped into the zinc containing base material forming the first target 120 with a desired dopant concentration. In one embodiment, the dopant materials may include one or more of aluminum containing materials, boron containing materials, titanium containing materials, tantalum containing materials, tungsten containing materials, alloys thereof, combinations thereof and the like. In one embodiment, the first target 120 may be fabricated from a zinc oxide material having dopants, such as, aluminum oxide, aluminum metal, titanium oxide, tantalum oxide, tungsten oxide, boron oxide and the like, doped therein. In one embodiment, the dopant concentration, such as aluminum oxide or aluminum metal in the zinc containing material comprising the first target 120 is controlled between about 0.1 percent by weight and about 10 percent by weight, such as between about 0.25 percent by weight and about 3 percent by weight.

In another embodiment, different dopant materials, such as aluminum containing materials, niobium containing materials, tungsten containing materials, alloys thereof, combinations thereof and the like, may also be doped into a titanium, tantalum, or alumium containing base material forming the second target 121 with a desired dopant concentration. In one embodiment, the dopant materials may include one or more of aluminum containing materials, niobium containing materials, tungsten containing materials, alloys thereof, combinations thereof and the like. In one embodiment, the second target 121 may be fabricated from a titanium oxide material having dopants, such as, aluminum oxide, aluminum metal, niobium metal, niobium oxide, and the like, doped therein. In an exemplary embodiment, the second target 121 may be fabricated from a titanium oxide material having niobium metal doped therein. The dopant concentration in the titanium containing material comprising the second target 121 is controlled less than 1 percent by weight, for example, between about 0.1 percent by weight and about 15 percent by weight, such as about 0.25 percent by weight and about 10 percent by weight.

By controlling different target materials of the first and the second target 120, 121, the material layers sputtered therefrom may be consecutively deposited on the substrate 150 to form different material layers as desired on the substrate 150. In the embodiment wherein two or more material layers are required to form on the substrate surface, a third target (not shown) may be installed in the processing chamber 100 followed by the second target 121 utilized to form a third material layer on the substrate surface.

In one embodiment, the first target 120 is fabricated from a zinc and aluminum alloy having a desired ratio of zinc element to aluminum element. The aluminum elements comprising the first target 120 assists maintaining the target conductivity within a desired range so as to efficiently enable a uniform sputter process across the target surface. The aluminum elements in the first target 120 is also believed to increase film transmittance when sputtered off and deposited onto the substrate 150. In one embodiment, the concentration of the aluminum element comprising the first zinc target 120 is controlled between about 0.25 percent by weight and about 3 percent by weight. In embodiments wherein the first target 120 is fabricated from ZnO and Al₂O₃ alloy, the Al₂O₃ dopant concentration in the ZnO base target material is controlled between about 0.25 percent by weight and about 3 percent by weight.

In another embodiment, the second target 121 is fabricated from a titanium oxide base material and niobium (Nb) metal having a desired ratio of titanium element to niobium element. The niobium elements in the second target 121 is also believed to increase film transmittance, film conductivity, and reduce light absorption when sputtered off and deposited onto the substrate 150. In one embodiment, the concentration of the niobium element comprising the second titanium oxide base target 121 is controlled less than 1 percent by weight. In embodiments wherein the second target 121 is fabricated from TiO₂ and Nb alloy, the Nb dopant concentration in the TiO₂ base target material is controlled less than 1 percent by weight. In another embodiment, the second target 121 may be fabricated from a tantalum oxide base material or aluminum oxide layer as needed.

Optionally, a magnetron assembly (not shown) may be optionally mounted above the targets 120, 121 which enhance efficient sputtering materials from the targets 120, 121 during processing. Examples of the magnetron assembly include a linear magnetron, a serpentine magnetron, a spiral magnetron, a double-digitated magnetron and a rectangularized spiral magnetron, among others.

A gas source 128 supplies process gases into the processing volume 140 through a gas supply inlet 126 formed through the top wall 104 and/or other wall of the chamber 100. In one embodiment, process gases may include inert gases, non-reactive gases, and reactive gases. Examples of process gases that may be provided by the gas source 128 include, but not limited to, argon gas (Ar), helium (He), nitrogen gas (N₂), oxygen gas (O₂), H₂, NO₂, N₂O and H₂O among others. It is noted that the location, number and distribution of the gas source 128 and the gas supply inlet 126 may be varied and selected according to different designs and configurations of the specific processing chamber 100.

A pumping device 142 is coupled to the process volume 140 to evacuate and control the pressure therein. In one embodiment, the pressure level of the interior processing region 140 of the process chamber 100 may be maintained at about 1 Torr or less. In another embodiment, the pressure level within the processing chamber 100 may be maintained at about 10⁻³ Torr or less. In yet another embodiment, the pressure level within the processing chamber 100 may be maintained at about 10⁻⁵ Torr to about 10⁻⁷ Torr. In another embodiment, the pressure level of the process chamber 100 may be maintained at about 10⁻⁷ Torr or less.

A substrate carrier system 152 is disposed in the interior processing region 140 to carry and convey a plurality of substrates 150 disposed in the processing chamber 100. In one embodiment, the substrate carrier system 152 is disposed on the bottom wall 102 of the processing chamber 100. The substrate carrier system 152 includes a plurality of cover panels 114 disposed between a plurality of rollers 112. The rollers 112 may be positioned in a spaced-apart relationship. The rollers 112 may be actuated by actuating device (not shown) to rotate the rollers 112 about an axis 164 having a fixed position in the processing chamber 100. The rollers 112 may be rotated clockwise or counter-clockwise to advance (a forward direction shown by arrow 116a) or backward (a backward direction shown by arrow 116b) the substrates 150 disposed thereon. As the rollers 112 rotate, the substrate 150 is advanced over the cover panels 114, consecutively passing under the first and the second target 120, 121 so as to receive the materials sputtered therefrom to deposit different material layers on the substrate 150. In one embodiment, the rollers 112 may be fabricated from a metallic material, such as Al, Cu, stainless steel, or metallic alloys, among others.

A top portion of the rollers 112 is exposed to the processing region 140 between the cover panels 114, thus defining a substrate support plane that supports the substrate 150 above the cover panels 114. During processing, the substrates 150 enter the processing chamber 100 through the back access port 132. One or more of the rollers 112 are actuated to rotate, thereby advancing the substrate 150 across the rollers 112 in the forward direction 116a through the processing region 140 for deposition. As the substrate 150 advances, the materials sputtered from the first and the second targets 120, 121 fall down and deposit on the substrate 150 to consecutively form a transparent conductive layer and a conductive contact layer with desired film properties on the substrate 150. As the substrate 150 continues to advance, the materials sputtered from different targets, such as a third target (not shown), are consecutively deposited on the substrate surface, thereby forming a desired film layer on the substrate surface.

In order to deposit the conductive contact layer and the transparent conductive layer on the substrate 150 with high quality, an optional insulating member 110 electrically isolates the rollers 112 from ground. The insulating member 110 supports the rollers 112 while interrupting the electrical path between the rollers 112 and a grounded surface, such as the processing chamber 100. In one embodiment, the insulating mechanism 110 may be in form of an insulating pad fabricated from an insulating material, such as rubber, glass, polymer, plastic, and polyphenylene sulfide (PPS), polyetheretherketone (PEEK) or other suitable insulating material that can electrically isolate the rollers from the bottom wall 102 of the processing chamber 100. In one embodiment, the insulating pad 110 is a non-conductive material, such as polyphenylene sulfide (PPS), polyetheretherketone (PEEK), or the like.

A controller 148 is coupled to the processing chamber 100. The controller 148 includes a central processing unit (CPU) 160, a memory 158, and support circuits 162. The controller 148 is utilized to control the process sequence, regulating the gas flows from the gas source 128 into the chamber 100 and controlling ion bombardment of the targets 120, 121. The CPU 160 may be of any form of a general purpose computer processor that can be used in an industrial setting. The software routines can be stored in the memory 158, such as random access memory, read only memory, floppy or hard disk drive, or other form of digital storage. The support circuits 162 are conventionally coupled to the CPU 160 and may comprise cache, clock circuits, input/output subsystems, power supplies, and the like. The software routines, when executed by the CPU 160, transform the CPU into a specific purpose computer (controller) 148 that controls the processing chamber 100 such that the processes are performed in accordance with the present invention. The software routines may also be stored and/or executed by a second controller (not shown) that is located remotely from the processing chamber 100.

During processing, as the substrate 150 is advanced by the roller 112, the material is sputtered from the targets 120, 121 and consecutively deposited on the surface of the substrate 150. The targets 120, 121 are biased by the power source 130, 131 to maintain a plasma 122, 123 formed from the process gases supplied by the gas source 128 and biased toward the substrate surface (as shown by arrows 124). The ions from the plasma are accelerated toward and strike the targets 120, 121, causing target material to be dislodged from the targets 120, 121. The dislodged target material and process gases form a layer on the substrate 150 with a desired composition.

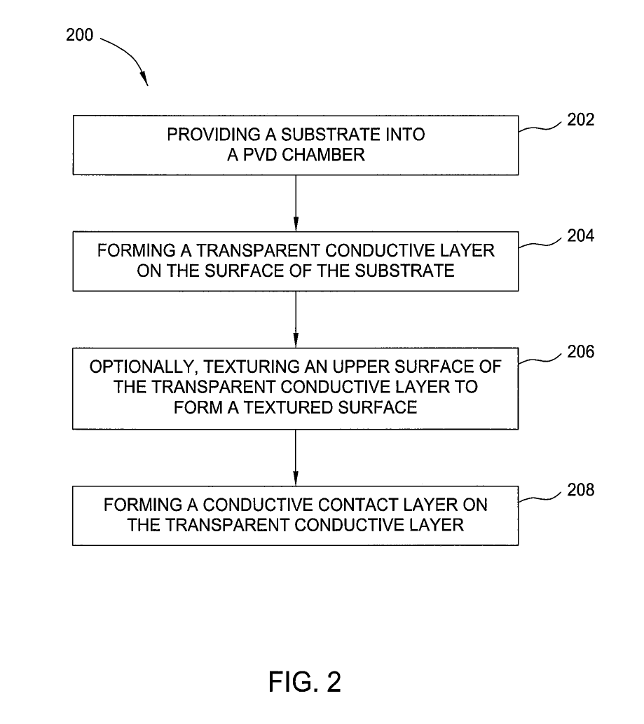

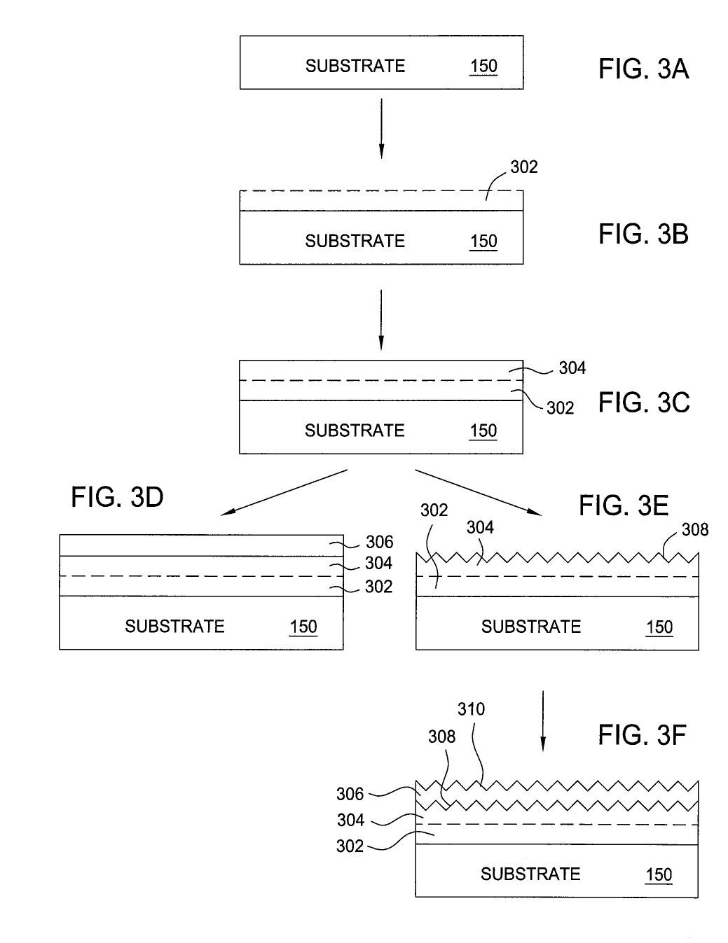

FIG. 2 is a flow diagram of one embodiment of a deposition process 200 that may be practiced in the processing chamber 100 or other suitable processing chamber to form a conductive contact layer on a transparent conductive layer on the substrate 150. FIGS. 3A-3F are schematic cross-sectional views of a portion of the substrate 150 utilized to form thin film PV solar cell corresponding to various stages of the deposition process 200. Although the deposition process 200 may be illustrated for forming contact conductive layer and transparent conductive layer in FIGS. 3A-3F for forming solar cell devices, the deposition process 200 may be beneficially utilized to form other structures. The process 200 may be stored in the memory 158 as instructions that when executed by the controller 148, cause the process 200 to be performed in the processing chamber 100. In embodiment depicted in FIG. 2, the process 200 is performed in a Thin Film Solar PVD system, such as an ATON® system, available from Applied Materials, Inc.

The process 200 begins at step 202 by transferring (i.e., providing) the substrate 150, as shown in FIG. 3A, to a processing chamber, such as the processing chamber 100 in FIG. 1. In the embodiment depicted in FIG. 3A, the substrate 150 may be thin sheet of metal, plastic, organic material, silicon, glass, quartz, or polymer, or other suitable material. The substrate 150 may have a surface area greater than about 1 square meters, such as greater than about 2 square meters. Alternatively, the substrate 150 may be configured to form thin film PV solar cell, or other types of solar cells, such as crystalline, microcrystalline or other type of silicon-based thin films as needed.

In one embodiment, the substrate 150 may have an optional barrier layer 302 formed on the surface of the substrate 150, as shown in FIG. 3B. The barrier layer 302 may reduce contact resistance and improve interface adhesion, transmission of light, and refractive index match to the transparent conductive layer which will be subsequently formed on the barrier layer 302. In one embodiment, the barrier layer 302 may be a silicon oxynitride (SiON) layer, silicon oxycarbide (SiOC), carbon doped silicon oxynitride (SiOCN), silicon oxide (SiO₂) layer, titanium oxide (TiO₂), tin oxide (SnO₂), aluminum oxide (Al₂O₃) layer, fluorinated tin oxide (SnO₂:F), carbon doped hydrogenated silicon oxide (SiOₓ:H:C), combinations thereof and the like. In one embodiment, the barrier layer 302 may have a thickness between about 100 Å and about 600 Å, such as between about 200 Å and about 400 Å.

At step 204, a first reactive sputter process is performed to form a transparent conductive layer 304 on the substrate 150, as shown in FIG. 3C. As discussed above, as the substrate 150 is advanced in the processing chamber 100, the substrate 150 may be positioned below the first target 120 to receive materials sputtered therefrom to deposit the transparent conductive layer 304 on the substrate 150. In one embodiment, the first target 120 is configured to have a zinc containing material to deposit a zinc containing material as the transparent conductive layer 304 on the substrate surface. In another embodiment, the first target 120 is configured to have dopant selected from a group consisting of aluminum containing materials, boron containing materials, titanium containing materials, tantalum containing materials, tungsten containing materials, alloys thereof, combinations thereof and the like formed in the zinc containing material. In one embodiment, the dopant formed within the zinc containing material is an aluminum oxide. The aluminum oxide dopant forms an aluminum oxide doped zinc oxide (AZO) layer as the transparent conductive layer 304 on the substrate surface. In one embodiment, the transparent conductive layer 304 is an aluminum oxide doped zinc oxide (AZO) layer having an aluminum oxide dopant concentration between about 0.25 percent by weight and about 3 percent by weight formed in the zinc oxide layer. In one embodiment, the transparent conductive layer 304 may have a thickness between about 5000 Å and about 12000 Å.

During sputtering, a process gas mixture may be supplied into the processing chamber 100 to assist bombarding the source material from the first target 120 and reacts with the sputtered material to form the desired transparent conductive layer 304 on the substrate surface. In one embodiment, the gas mixture may include reactive gas, non-reactive gas, inert gas, and the like. Examples of non-reactive gas include, but not limited to, inert gases, such as Ar, He, Xe, and Kr, among other suitable gases. Examples of reactive gas include, but not limited to, O₂, N₂, N₂O, NO₂, H₂, NH₃ and H₂O, among others.

In one embodiment, the argon (Ar) gas supplied into the processing chamber 100 assists bombarding the target materials from the target surface. The sputtered materials from the target react with the reactive gas in the sputter process chamber, thereby forming the transparent conductive layer 304 having desired film properties on the substrate 150.

In one particular embodiment depicted here, the process gas mixture supplied into the sputter process chamber includes at least one of Ar, O₂ or H₂. In one embodiment, the O₂ gas may be supplied at a flow rate between about 0 sccm and about 100 sccm, such as between about 5 sccm and about 30 sccm. The Ar gas may be supplied into the processing chamber 100 at a flow rate between about 100 sccm and between 500 sccm. The H₂ gas may be supplied into the processing chamber 100 at a flow rate between about 0 sccm and between 100 sccm, such as between about 5 sccm and about 30 sccm. Alternatively, O₂ gas flow may be controlled at a flow rate per total flow rate between about 1 percent and about 10 percent. H₂ gas flow may be controlled at a flow rate per total flow rate between about 1 percent and about 10 percent. RF power is supplied to the first target 120 to sputter the source material from the first target 120 which reacts with the supplied gas mixture. As a high voltage power is supplied to the first target 120, the metal material is sputtered from the first target 120 in form of metallic ions, such as Zn⁺, Zn²⁺, Al³⁺ and the like. The bias power applied between the first target 120 and the substrate support 152 maintains the plasma 124 formed from the gas mixture in the processing chamber 100. The ions from the gas mixture in the plasma bombard and sputter off material from the first target 120. The ions from the reactive gases react with the growing sputtered film to form a layer with desired composition on the substrate 150. In one embodiment, a RF power may be supplied to the target between about 1000 Watts and about 60000 Watts. Alternatively, the RF power maybe controlled by supplying a RF power density may be supplied between about 0.15 Watts per centimeter square and about 15 Watts per centimeter square, for example, about 4 Watts per centimeter square and about 8 Watts per centimeter square. Alternatively, the DC power may be supplied between about 0.15 Watts per centimeter square and about 15 Watts per centimeter square, for example, about 4 Watts per centimeter square and about 8 Watts per centimeter square.

Several process parameters may be regulated at step 204. In one embodiment, a pressure of the gas mixture in the processing chamber 100 is regulated between about 2 mTorr and about 10 mTorr. The substrate temperature may be maintained between about 25 degrees Celsius and about 100 degrees Celsius. The processing time may be processed at a predetermined processing period or after a desired thickness of the transparent conductive layer 304 is deposited on the substrate 150. In one embodiment, the process time may be processed at between about 30 seconds and about 400 seconds. In the embodiment wherein a substrate with different dimension is desired to be processed, process temperature, pressure and spacing configured in a process chamber with different dimension do not change in accordance with a change in substrate and/or chamber size.

At step 206, an optional texturing process may be performed on the transparent conductive layer 304 to form a textured surface 308 on the transparent conductive layer 304, as shown in FIG. 3E. Alternatively, in the embodiment wherein the optional texturing processing is not performed, the substrate 150 may be transferred to perform the subsequent process described at step 208 with referenced to FIG. 3D, which will be discussed further below. In the embodiment wherein the optional texturing process is performed on the substrate 150 at step 206, the optional texturing process may slightly etch, treat and texture the transparent conductive layer 304 to form the textured surface 308 on the transparent conductive layer 304. The texturing process may be a wet etching process, or a dry process, such as a gentle/light plasma process, or a surface treatment process that may change the surface roughness, morphology and surface topography of the transparent conductive layer 304.

It is believed that an uneven surface topography or higher surface roughness formed in the transparent conductive layer 304 may assist light scattering and trapping within the transparent conductive layer 304, thereby improving light transmission therethrough to solar cell junction subsequently formed on the substrate 150. In one embodiment, the textured surface 308 may have a surface roughness (e.g., surface step height) between about 20 nm and about 200 nm.

At step 208, a second reactive sputter process is performed to form a conductive contact layer 306 on the transparent conductive layer 304 on the substrate 150, as shown in FIG. 3F. As the transparent conductive layer 304 may be textured to have an uneven surface, the conductive contact layer 306 formed thereon may follow the topography of the transparent conductive layer 304 to deposit thereon and form an uneven surface 310 on the conductive contact layer 306. In the embodiment wherein the optional texturing process described at step 306 is not performed, the second reactive sputter process may be performed to directly deposit the conductive contact layer 306 on the non-textured surface of the transparent conductive layer 304, as shown in FIG. 3D. After the substrate 150 passed below the first target 120, the substrate 150 is advanced in the processing chamber 100 to a position below the second target 121. The substrate 150 then receives materials sputtered from the second target 121 to deposit the conductive contact layer 306 on the substrate 150. In one embodiment, the second target 121 is configured to have a titanium containing material, a tantalum containing material or aluminum containing material having desired dopants formed therein to form the conductive contact layer 306 on the substrate surface. Dopants selected from a group consisting of aluminum containing materials, niobium containing materials, tungsten containing materials, alloys thereof, combinations thereof and the like may be doped into the second target 121 of the titanium containing material, tantalum containing material or aluminum containing material to form the conductive contact layer 306. In one embodiment, the second target 120 is configured to have a niobium doped titanium oxide material to deposit a niobium doped titanium oxide layer as the conductive contact layer 306 on the substrate surface. The niobium doped titanium oxide layer may have a formula NbₓTi_{y}O_{z} where x has a range between 0.01 and 0.1 and y has a range of between 0.9 and 0.99 and z is about 2.

In one embodiment, the conductive contact layer 306 is a niobium doped titanium oxide layer having a niobium dopant concentration less than 1 percent by weight formed in the titanium oxide layer. In one embodiment, the conductive contact layer 306 may have a thickness between about 200 Å and about 700 Å. In another embodiment, the conductive contact layer 306 may be a tantalum oxide layer and an aluminum oxide layer.

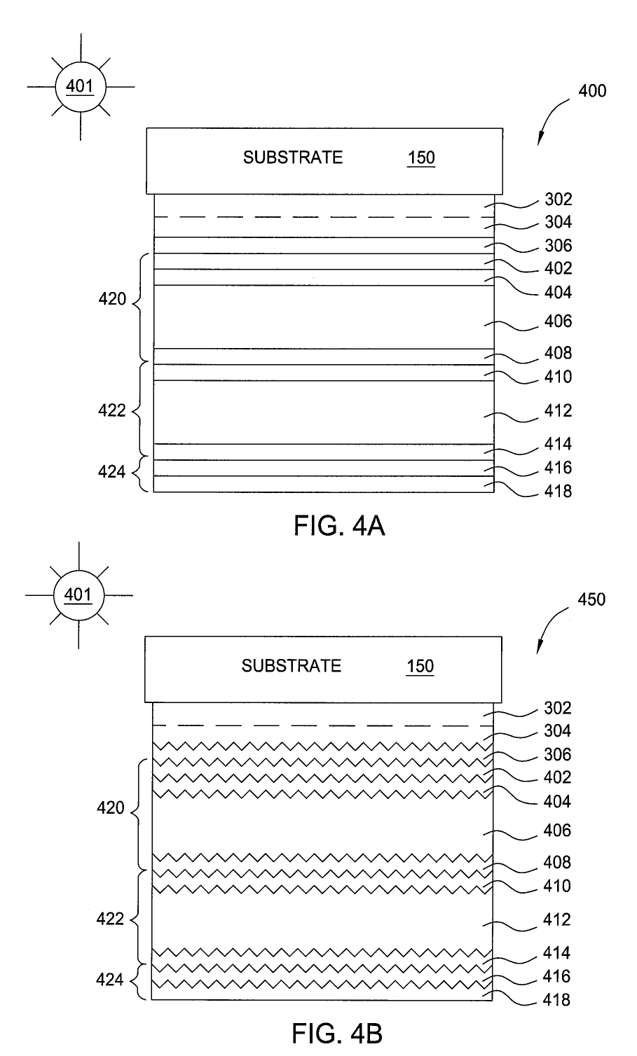

In one embodiment, the conductive contact layer 306 may provide a good contact interface between the transparent conductive layer 304 and subsequent to-be-formed solar cell junctions, which will be further described below with referenced to FIGS. 4A-4B. The conductive contact layer 306 is formed to have a high film transparency to help reduce light loss traveling from the transparent conductive layer 304 to the subsequent to-be-formed solar cell junctions. Furthermore, the conductive contact layer 306 also assist reducing contact resistance and improving film conductivity between the transparent conductive layer 304 and the subsequent to-be-formed solar cell junctions so as to maintain high current conversion efficiency to the photoelectric conversion unit. In one embodiment, the conductive contact layer 306 may have a film conductivity between about 2×10⁻⁴ ohm.cm and about 2×10⁻³ ohm.cm.

Additionally, the optical and electrical film properties of the conductive contact layer 306 may be adjusted or tuned to have a different film optical characteristic so as to match and provide a similar optical film property to the nearby adjacent layers. For example, refractive indexes of the transparent conductive layer 304 and the adjacent film layers utilized to form solar junction cells often have significant difference, as transparent conductive layer 304 is often fabricated from a conductive material and the film layers utilized to form solar junction cells are often fabricated from dielectric layers, such as a silicon based material. In order to reduce and compensate the refractive index gap in between these layers and provide a smooth transition of the refractive index in these layers, the conductive contact layer 306 formed and inserted therebetween may efficiently serve as a refractive index matching layer (e.g., a buffer layer) to reduce and compensate the sudden refractive index change in these layers as light passes therethrough. Accordingly, the conductive contact layer 306 is turned and adjusted to have a refractive index between the refractive index of the transparent conductive layer 304 and the dielectric layers utilized to form solar junction cells. In one embodiment, the refractive index of the conductive contact layer 306 is controlled at between about 2.0 and about 2.8, such as about 2.3, as the refractive index of the transparent conductive layer 304 is often about 1.8 to 2.1 and the dielectric layer, such as a silicon based layer, is often about 3.6 to 3.8.

Furthermore, the conductive contact layer 306 may have a high film mobility so as to help carry and generate electrons to the adjacent layers to the solar cell junctions. In one embodiment, the conductive contact layer 306 may have a film mobility between about 20 V.s/cm² and about 90 V.s/cm².

During sputtering, the process gas mixture supplied at step 204 may also be supplied at step 208 to assist bombarding the source material from the second target 121 and reacting with the sputtered material to form the desired conductive contact layer 306 on the substrate surface. Alternatively, the process gas mixture may be varied to supply different gases at step 208 for different process requirements and needs. Similarly, the gas mixture supplied at step 308 may include reactive gas, non-reactive gas, inert gas, and the like, as described above. Examples of non-reactive gas include, but not limited to, inert gas, such as Ar, He, Xe, and Kr, or other suitable gases. Examples of reactive gas include, but not limited to, O₂, N₂, N₂O, NO₂, H₂, NH₃, H₂O, among others. Other process parameters may be maintained similar, the same or varied from the step 304. In one embodiment, the process parameters performed at step 308 is the same as the process parameters performed at step 304.

Therefore, by utilizing a reactive sputter processing chamber, such as the processing chamber 100 depicted in FIG. 1, having different materials of targets 120, 121 formed within the processing chamber, the transparent conductive layer 304 and the conductive contact layer 306 may be formed in a single reactive sputter processing chamber (e.g., PVD chamber) without breaking vacuum. The integrated deposition method of the transparent conductive layer 304 and the conductive contact layer 306 reduces likelihood of forming native oxides or contaminants on the substrate surface, which may adversely increase contact resistance and reduce film conductivity. Furthermore, the integrated deposition method may also increase throughput of forming transparent conductive layer 304 and the conductive contact layer 306, thereby reducing manufacture cost and overall manufacture cycle time.

FIGS. 4A-4B depict an exemplary cross sectional view of tandem type PV solar cells 400, 450 having the conductive contact layer 306 formed between the transparent conductive layer 304 and junction cell in accordance with one embodiment of the present invention. Similar to the structures depicted in FIG. 3D, the substrate 150 may have the optional barrier layer 302, transparent conductive layer 304 and the conductive contact layer 306 consecutively formed thereon, as shown in FIG. 4A. In the embodiment wherein the optional texturing process described at step 206 is performed, the transparent conductive layer 304 may have a textured surface and the subsequent layers formed thereon may follow the topography of the transparent conductive layer 304 to have textured surface formed thereon, as shown in FIG. 4B. After the conductive contact layer 306 is formed on the substrate, a first photoelectric conversion junction cell 420 is formed on conductive contact layer 306 disposed on the substrate 150. The first photoelectric junction cell 420 includes a heavily doped p-type semiconductor layer 402, a p-type semiconductor layer 404, a n-type semiconductor layer 408, and an intrinsic type (i-type) semiconductor layer 406 sandwiched therebetween as a photoelectric conversion layer. An optional dielectric layer (not shown) may be disposed between intrinsic type (i-type) semiconductor layer 406 and the n-type semiconductor layer 408 as needed. In one embodiment, the optional dielectric layer may be a silicon layer including amorphous or poly silicon layer, SiON, SiN, SiC, SiOC, silicon oxide (SiO₂) layer, doped silicon layer, or any suitable silicon containing layer.

The heavily doped p-type, p-type and n-type semiconductor layers 402, 404, 408 may be silicon based materials doped by an element selected either from Group III or V. A Group III element doped silicon film is referred to as a p-type silicon film, while a Group V element doped silicon film is referred to as a n-type silicon film. The heavily doped p-type semiconductor layer 402 is referred to the layers having higher Group III dopant concentration than the p-type semiconductor layer 404. In one embodiment, the n-type semiconductor layer 408 may be a phosphorus doped silicon film and the heavily doped p-type and p-type semiconductor layer 402, 404 may be a boron doped silicon film. The doped silicon films 402, 404, 408 include an amorphous silicon film (a-Si), a polycrystalline film (poly-Si), and a microcrystalline film (μc-Si) with a thickness between around 5 nm and about 50 nm. Alternatively, the doped element in semiconductor layers 402, 404, 408 may be selected to meet device requirements of the PV solar cells 400, 450. The n-type and heavily doped p-type and p-type semiconductor layers 408, 402, 404 may be deposited by a CVD process or other suitable deposition process.

The i-type semiconductor layer 406 is a non-doped type silicon based film. The i-type semiconductor layer 406 may be deposited under process conditions controlled to provide film properties having improved photoelectric conversion efficiency. In one embodiment, the i-type semiconductor layer 406 may be fabricated from i-type polycrystalline silicon (poly-Si), i-type microcrystalline silicon film (μc-Si), amorphous silicon (a-Si), or hydrogenated amorphous silicon (a-Si).

After the first photoelectric conversion junction cell 420 is formed on the conductive contact layer 306, an optional second photoelectric conversion junction cell 422 may be formed on the photoelectric conversion junction cell 420. In the embodiment wherein the second photoelectric conversion junction cell 422 is not formed and present on the first photoelectric conversion junction cell 420, the solar cell 400 may be formed as a single junction having only one photoelectric conversion junction cell 420. The structure of the second conversion junction cell 422 is similar to the first photoelectric conversion junction cell 420 to assist absorbing light with different spectrum and retain light in the junction cells for a longer time to improve conversion efficiency. In one embodiment, a p-type semiconductor layer 410, a n-type semiconductor layer 414, and an intrinsic type (i-type) semiconductor layer 412 sandwiched therebetween as a photoelectric conversion layer. An optional dielectric layer (not shown) may be disposed on top of the n-type semiconductor layer 414 as needed. In one embodiment, the optional dielectric layer may be a heavily doped n-type semiconductor layer. The doped silicon films 410, 414 include an amorphous silicon film (a-Si), a polycrystalline film (poly-Si), and a microcrystalline film (μc-Si) with a thickness between around 5 nm and about 50 nm. Alternatively, the doped element in semiconductor layers 410, 414 may be selected to meet device requirements of the PV solar cells 400, 450. The p-type and the n-type 410, 414 may be deposited by a CVD process or other suitable deposition process. The i-type semiconductor layer 412 is a non-doped type silicon based film. The i-type semiconductor layer 412 may be deposited under process conditions controlled to provide film properties having improved photoelectric conversion efficiency. In one embodiment, the i-type semiconductor layer 412 may be fabricated from i-type polycrystalline silicon (poly-Si), i-type microcrystalline silicon film (μc-Si), amorphous silicon (a-Si), or hydrogenated amorphous silicon (a-Si).

After the first and the second conversion junction cell 420, 422 are formed on the substrate, a back reflector 424 is disposed on the second photoelectric conversion junction cell 422. In one embodiment, the back reflector 424 may be formed by a stacked film that includes a second transparent conductive layer 416 and a conductive layer 418. The conductive layer 418 may be at least one of Ti, Cr, Al, Ag, Au, Cu, Pt, or their alloys. The second transparent conductive layer 416 may be fabricated from a material similar to the first transparent conductive layer 304 formed on the substrate 150. Alternatively, the second transparent conductive layer 416 may be fabricated from a selected group consisting of tin oxide (SnO₂), indium tin oxide (ITO), zinc oxide (ZnO), or combinations thereof. In one exemplary embodiment, the transparent conductive layers 304, 416 may be fabricated from a ZnO layer having a desired Al₂O₃ dopant concentration formed in the ZnO layer.

In operation, the incident light 401 provided by the environment is supplied to the PV solar cell 400, 450. The light passes through the conductive contact layer 306 to the photoelectric conversion junction cell 420, 422 in the PV solar cell 400, 450 to absorb the light energy and convert the light energy into electrical energy by operation of the p-i-n junctions formed in the photoelectric conversion junction cell 420, 422, thereby generating electricity or energy.

Thus, methods for sputtering depositing a transparent conductive layer and a conductive contact layer with high film transparency, high film mobility, and low contact resistance are provided. The method advantageously produces a transparent conductive layer and a conductive contact layer having desired optical film properties in a single reactive sputter chamber, such as a PVD chamber. In this manner, the transparent conductive layer and the conductive contact layer efficiently increase the photoelectric conversion efficiency and device performance of the PV solar cell and reduce manufacture cost and cycle time.

While the foregoing is directed to embodiments of the present invention, other and further embodiments of the invention may be devised without departing from the basic scope thereof, and the scope thereof is determined by the claims that follow.

What is claimed is:

1. A method of sputter depositing a conductive contact layer, comprising:
forming a transparent conductive layer on a substrate by materials sputtered from a first target disposed in a reactive sputter chamber; and
forming a conductive contact layer on the transparent conductive layer by materials sputtered from a second target disposed in the reactive sputter chamber.

2. The method of claim 1, wherein the transparent conductive layer is a zinc containing material.

3. The method of claim 2, wherein the zinc containing material has dopants formed therein, wherein the dopants are selected from a group consisting of aluminum containing materials, boron containing materials, titanium containing materials, tantalum containing materials, tungsten containing materials, alloys thereof, combinations thereof.

4. The method of claim 1, wherein the transparent conductive layer is an aluminum oxide doped zinc oxide layer.

5. The method of claim 1, wherein the conductive contact layer is a titanium containing material, a tantalum containing material or a aluminum containing material.

6. The method of claim 5, wherein the titanium containing material has dopants formed therein, wherein the dopants are selected from a group consisting of aluminum containing materials, niobium containing materials, tungsten containing materials, alloys thereof and combinations thereof.

7. The method of claim 1, wherein the conductive contact layer is a niobium doped titanium oxide layer.

8. The method of claim 7, wherein the niobium doped into the titanium oxide layer has a dopant concentration less than 1 percent by weight.

9. The method of claim 1, further comprising:
a barrier layer disposed between the substrate and the transparent conductive layer.

10. The method of claim 9, wherein the barrier layer is fabricated from a material selected from a group consisting of silicon oxynitride (SiON) layer, silicon oxycarbide (SiOC), carbon doped silicon oxynitride (SiOCN), silicon oxide (SiO₂) layer, titanium oxide (TiO₂), tin oxide (SnO₂), aluminum oxide (AlO₃) layer, fluorinated tin oxide (SnO₂:F), carbon doped hydrogenated silicon oxide (SiOₓ:H:C), and combinations thereof.

11. The method of claim 1, wherein the conductive contact layer has a refractive index controlled between about 2.0 and about 2.8.

12. The method of claim 1, wherein the conductive contact layer has a thickness between about 200 Å and about 700 Å.

13. A method of forming a transparent conductive layer, comprising:
providing a substrate in a reactive sputter processing chamber;
forming a transparent conductive layer on the substrate in the reactive sputter processing chamber; and
forming a conductive contact layer on the transparent conductive layer in the reactive sputter processing chamber, wherein the conductive contact layer comprises dopants doped into a base material, wherein the dopants is selected from a group consisting of aluminum containing materials, niobium containing materials, tungsten containing materials, alloys thereof and combinations thereof, and the base material is a titanium containing material.

14. The method of claim 13, wherein the conductive contact layer is a niobium doped titanium oxide layer.

15. The method of claim 14, wherein the niobium doped into the titanium oxide layer has a dopant concentration less than 1 percent by weight.

16. The method of claim 13, wherein the conductive contact layer has a refractive index between about 2.0 and about 2.8.

17. The method of claim 13, wherein the conductive contact layer has a resistivity between about 2×10⁻⁴ ohm.cm and about 2×10⁻³ ohm.cm.

18. A film stack for a PV solar cell, comprising:
a substrate having a transparent conductive layer disposed thereon; and
a conductive contact layer deposited on the transparent conductive layer, wherein the conductive contact layer comprises a doped titanium containing base material, and wherein at least one dopant present in the base material is selected from a group consisting of aluminum containing materials, niobium containing materials, tungsten containing materials, alloys thereof and combinations thereof.

19. The film stack of claim 18 further comprising:
a first photoelectric junction cell disposed on the conductive contact layer, wherein the photoelectric junction cell further comprises:
an optional heavily doped p-type semiconductor layer;
a p-type semiconductor layer;
an intrinsic type semiconductor layer; and
a n-type semiconductor layer.

20. The film stack of claim 19, further comprising:
a second photoelectric junction cell formed over the first photoelectric junction cell.

21. The film stack of claim 18, wherein the conductive contact layer is a niobium doped titanium oxide layer.

22. The film stack of claim 21, wherein niobium doped into the titanium oxide layer has a dopant concentration less than about 1 percent by weight.

23. The film stack of claim 18, wherein the conductive contact layer has a refractive index between about 2.0 and about 2.8.

24. The film stack of claim 18, wherein the transparent conductive layer is an aluminum oxide doped zinc oxide layer.
